(19) United States
(12) Patent Application Publication
(10) Pub. No.: US 2026/0076236 A1
(43) Pub. Date: Mar. 12, 2026

(54) DEVICE INCLUDING SUBSTRATE WITH EMBEDDED COMPONENT

(71) Applicant: QUALCOMM Incorporated, San Diego, CA (US)

(72) Inventors: Heun Gun SHIN, San Diego, CA (US); Kyudong KANG, Seoul (KR); Tsu-Wei LIN, San Diego, CA (US)

(21) Appl. No.: 18/882,345

(22) Filed: Sep. 11, 2024

(51) Int. Cl. H01L 23/498; H01L 21/48; H01L 23/367; H01L 25/16

(52) U.S. Cl. CPC H10W 70/685; H10D 1/20; H10W 40/22; H10W 70/05; H10W 70/65; H10W 70/69; H10W 90/00

(57) ABSTRACT

A device includes a substrate that includes a multilayer dielectric-metal structure including sidewall(s) that define an embedding region within the multilayer dielectric-metal structure. The multilayer dielectric-metal structure includes dielectric layers and metal layers patterned to define metal lines. The multilayer dielectric-metal structure also includes component(s) disposed within the embedding region. The substrate includes PID layers coupled to surfaces of the multilayer dielectric-metal structure and to surfaces of the component(s). The substrate also includes a metal structure including a portion in contact with at least one of the sidewall(s) of the multilayer dielectric-metal structure and at least one sidewall of one of the component(s), where the portion of the metal structure electrically couples a component and the metal lines of the multilayer dielectric-metal structure.

### FIELD

Various features relate to substrates for integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, smaller form factor devices are generally more expensive to design and manufacture and small size can exacerbate other issues, such as heat management. As another example, more complex integrated circuit dies often have more interconnect demands. Thus, an integrated device package that includes more complex integrated circuit dies may be larger and/or more expensive to manufacture than an integrated device package that includes less complex integrated circuit dies.

As another example, performance of some circuits can be improved by inclusion of passive components, such as inductors, capacitors, and/or resistors. To illustrate, inductors can be used to adjust impedance of a radiofrequency (RF) circuit, which can improve efficiency by reducing return loss, reducing parasitic elements, lowering insertion loss, controlling harmonic distortion, improving bandwidth, etc. However, incorporating passive components into an integrated device package tends to increase the size of the integrated device package, and may affect other issues, such as cost.

### SUMMARY

Various features relate to integrated circuit devices.

One example provides a device that includes a substrate that includes a multilayer dielectric-metal structure including one or more sidewalls that define an embedding region within the multilayer dielectric-metal structure. The multilayer dielectric-metal structure includes first dielectric layers and first metal layers patterned to define first metal lines. A first component is disposed within the embedding region. The substrate includes a first photoimageable dielectric (PID) layer coupled to a first surface of the multilayer dielectric-metal structure and to a first surface of the first component, where the first surface of the multilayer dielectric-metal structure is adjacent to the one or more sidewalls of the multilayer dielectric-metal structure. The substrate also includes a second PID layer coupled to a second surface of the multilayer dielectric-metal structure and to a second surface of the first component, where the second surface of the multilayer dielectric-metal structure is adjacent to the one or more sidewalls of the multilayer dielectric-metal structure and is opposite the first surface of the multilayer dielectric-metal structure. The substrate further includes a first metal structure including a portion in contact with at least one of the one or more sidewalls of the multilayer dielectric-metal structure and at least one sidewall of the first component, where the portion of the first metal structure is electrically coupled to the first component and the first metal lines.

Another example provides a method of fabrication that includes positioning a first component within an opening of an embedding region defined by one or more sidewalls of a multilayer dielectric-metal structure. The multilayer dielectric-metal structure includes first dielectric layers and first metal layers patterned to define first metal lines. The method also includes forming a PID layer on the one or more sidewalls of the multilayer dielectric-metal structure and on one or more sidewalls of the first component. The method further includes forming a first metal structure including a portion in contact with at least one of the one or more sidewalls of the multilayer dielectric-metal structure and at least one of the one or more sidewalls of the first component, where the portion of the first metal structure is electrically coupled to the first component and the first metal lines. The method also includes forming one or more additional PID layers on one or more surfaces of the multilayer dielectric-metal structure that are adjacent to the one or more sidewalls of the multilayer dielectric-metal structure.

Another example provides a device that includes an integrated device and a substrate electrically coupled to the integrated device. The substrate includes a multilayer dielectric-metal structure including one or more sidewalls that define an embedding region within the multilayer dielectric-metal structure. The multilayer dielectric-metal structure includes first metal layers patterned to define first metal lines and first dielectric layers. The multilayer dielectric-metal structure also includes a first component disposed within the embedding region. The substrate includes a first PID layer coupled to a first surface of the multilayer dielectric-metal structure and to a first surface of the first component, where the first surface of the multilayer dielectric-metal structure is adjacent to the one or more sidewalls of the multilayer dielectric-metal structure. The substrate also includes a second PID layer coupled to a second surface of the multilayer dielectric-metal structure and to a second surface of the first component, where the second surface of the multilayer dielectric-metal structure is adjacent to the one or more sidewalls of the multilayer dielectric-metal structure and is opposite the first surface of the multilayer dielectric-metal structure. The substrate further includes a first metal structure including a portion in contact with at least one of the one or more sidewalls of the multilayer dielectric-metal structure and at least one sidewall of the first component, where the portion of the first metal structure is electrically coupled to the first component and the first metal lines.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1A illustrates a schematic cross-sectional profile view of an exemplary device that includes one or more components disposed within an embedding region of a substrate.

FIG. 1B illustrates a top view of a portion of the substrate of the exemplary device of FIG. 1A.

FIG. 2 illustrates a schematic perspective view of an example of a component disposed in a portion of a multilayer dielectric-metal structure of the substrate of the exemplary device of FIG. 1A.

FIG. 3A illustrates a schematic cross-sectional profile view of another exemplary device that includes one or more components disposed within an embedding region of a substrate.

FIG. 3B illustrates a top view of a portion of the substrate of the exemplary device of FIG. 3A.

FIG. 3C illustrates a schematic cross-sectional profile view of another exemplary device that includes one or more components disposed within an embedding region of a substrate.

FIG. 3D illustrates a schematic cross-sectional profile view of another exemplary device that includes one or more components disposed within an embedding region of a substrate.

FIGS. 4A, 4B, and 4C together illustrate an exemplary sequence for fabricating a device that includes one or more components disposed within an embedding region of a substrate.

FIG. 5 illustrates an exemplary flow diagram of a method of semiconductor fabrication for a device that includes one or more components disposed within an embedding region of a substrate.

FIG. 6 illustrates various electronic devices that may integrate an exemplary device that includes one or more components disposed within an embedding region of a substrate described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures, and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to couple to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Some integrated device packages use a substrate that includes various metal and dielectric layers built up on (e.g., laminated onto) a core layer. Such substrates can be referred to as “cored substrates,” in contrast with “coreless substrates” in which metal and dielectric layers are built up without a core layer. In some cases, when a cored substrate is used, a passive component can be embedded within the core and electrically coupled to another device (e.g., an integrated circuit die) that is attached to the substrate. This arrangement can enable positioning of the passive component relatively near the integrated circuit die, which can provide some electrical benefits; however, cored substrates are generally significantly thicker than coreless substrates, as a result, integrated device packages that use cored substrates tend to be thicker than similar integrated device packages that use coreless substrates. An additional concern associated with embedding components within a substrate (whether cored or coreless) is that electrical interconnects to embedded components are generally formed using laser drilling or other similar via formation techniques, which can limit routing options in various layers of the substrate.

Aspects disclosed herein address the challenges associated with use of embedded components within a substrate by forming a coreless substrate using dielectric materials that can be patterned to only a portion of their thickness, which enables such dielectric materials to retain embedded components in a manner that leaves some surfaces of the components exposed. For example, a component can be embedded (e.g., fully encased within or partially encased within) a layer of photoimageable dielectric (PID), and the PID can be patterned such that only portions of the PID on a portion of sides of the component remain. These portions of the PID are sufficient to retain the component during subsequent operations to form the substrate. Forming a substrate in this manner enables embedding of components within coreless substrates, resulting in smaller integrated device packages.

Further, a substrate formed in this manner can include electrical connections to the embedded component that do not require laser drilling. To illustrate, plating, lamination, or other metal deposition operations can be used to form a patterned metal layer of the substrate, where the patterned metal layer includes electrical connections to the component. Additionally, or alternatively, the component can be embedded between one or more sidewalls defining an opening in one or more layers of the substrate, and one or more electrical connections to the component can be disposed between the component and the one or more sidewalls. Forming electrical connections to the embedded component in a patterned metal layer of the substrate, between the component and the one or more sidewalls of the substrate, or both, increases the availability of portions of the substrate over and/or under the component for routing of electrical connections.

Additional benefits can be achieved for certain types of embedded components. For example, integrated device packages that include inductors often form inductor coils by patterning metal layers of the substrate. Such inductors take up area of the substrate that could be used for other purposes, such as to attach devices or provide conductors for electrically interconnecting devices. Additionally, due to the magnetic field orientation of such inductors the substrate may include a ground plane, which can reduce magnetic field flux of the inductors. In contrast, the disclosed techniques can be used to embed an inductor within the substrate, freeing up area that would otherwise be used to form the inductor for other uses. Additionally, such an inductor can be embedded in an orientation such that no ground plane is needed, which can reduce the number of metal layers of the substrate (and therefore the thickness of the substrate). Furthermore, since the magnetic field flux of the inductor is not cut off by a ground plane, a smaller inductor can be used to provide the same inductance to the substrate as compared to an inductor formed by patterning metal layers of the substrate.

The techniques described herein can also, or alternatively, be used for non-electrical components. For example, a heat sink can be embedded within a substrate using the disclosed techniques to facilitate removal of heat from one or more devices coupled to the substrate.

### Exemplary Device Including a Substrate with One or More Embedded Components

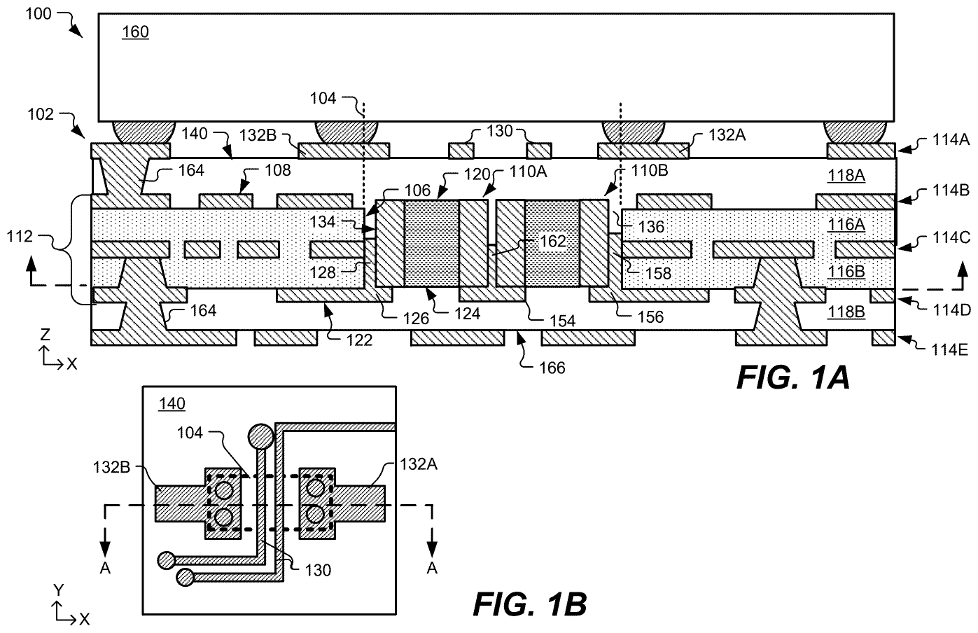

FIG. 1A illustrates a schematic cross-sectional profile view of an exemplary device 100 that includes one or more components 110 (e.g., a component 110A and a component 110B in FIG. 1A) disposed within an embedding region of a multilayer dielectric-metal structure 112 that forms a portion of a substrate 102. In the example illustrated in FIG. 1A, the device 100 includes the substrate 102 and an integrated device 160 (e.g., one or more dies, one or more die stacks, etc.) electrically coupled to the substrate 102. FIG. 1B illustrates a schematic top view of a portion of the substrate 102 with the integrated device 160 omitted. In particular, FIG. 1B shows a surface 140 of the substrate 102 in an area around an embedding region 104 of the substrate 102. FIG. 1B also shows a cutline AA associated with the cross-sectional profile view of FIG. 1A.

The multilayer dielectric-metal structure 112 of the substrate 102 includes multiple dielectric layers 116 intermingled with multiple metal layers 114. For example, in FIG. 1A, the metal layers 114 of the multilayer dielectric-metal structure 112 include a metal layer 114B, a metal layer 114C, and a metal layer 114D, and the dielectric layers 116 include a dielectric layer 116A and a dielectric layer 116B. The metal layers 114 are patterned to define metal lines (e.g., traces), and various ones of the metal lines can be interconnected to one another or to other features of the substrate 102 by conductive vias. Although the multilayer dielectric-metal structure 112 is illustrated in FIG. 1A as including three metal layers 114B-114D and two dielectric layers 116A, 116B, in other examples, the multilayer dielectric-metal structure 112 can include more than three metal layers, more than two dielectric layers, or both.

In FIGS. 1A and 1B, the embedding region 104 is defined in the multilayer dielectric-metal structure 112. For example, the embedding region 104 corresponds to or includes an opening in the multilayer dielectric-metal structure 112 bounded by one or more sidewalls 106. The sidewall(s) 106 are adjacent to a surface (e.g., a top surface, a bottom surface, or both) of the multilayer dielectric-metal structure 112. The sidewall(s) 106 include portions of the dielectric layers 116, portions of the metal layers 114B, 114C, 114D, or both. For example, in FIG. 1A, the embedding region 104 is bounded by portions of each of the dielectric layers 116, a portion of the metal layer 114C, and a portion of the metal layer 114D along the sidewall(s) 106. In this example, the metal layer 114B is patterned such that portions of the metal layer 114B are offset from the embedding region 104; however, such patterning is merely illustrative and is not limiting.

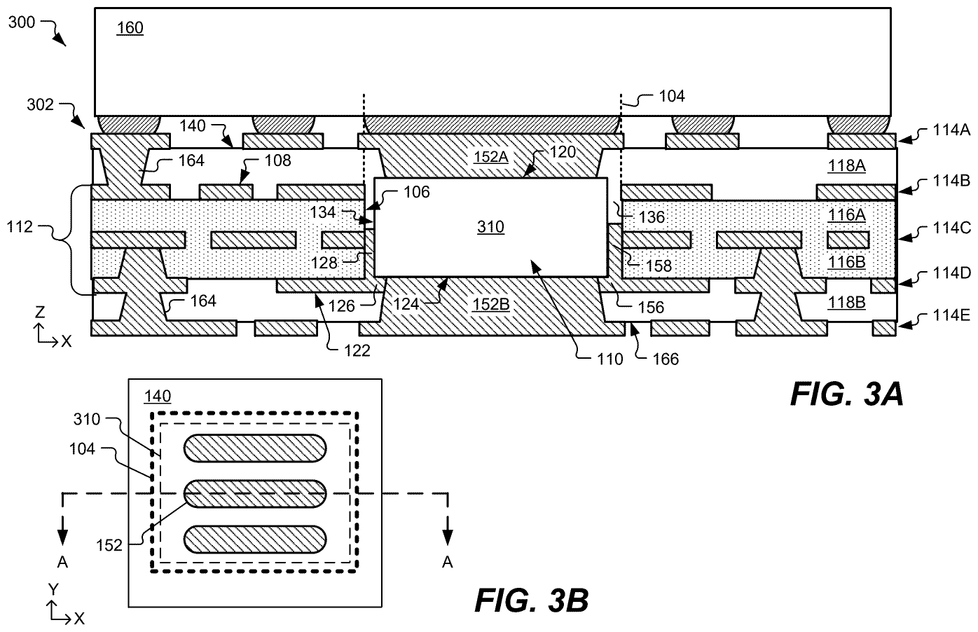

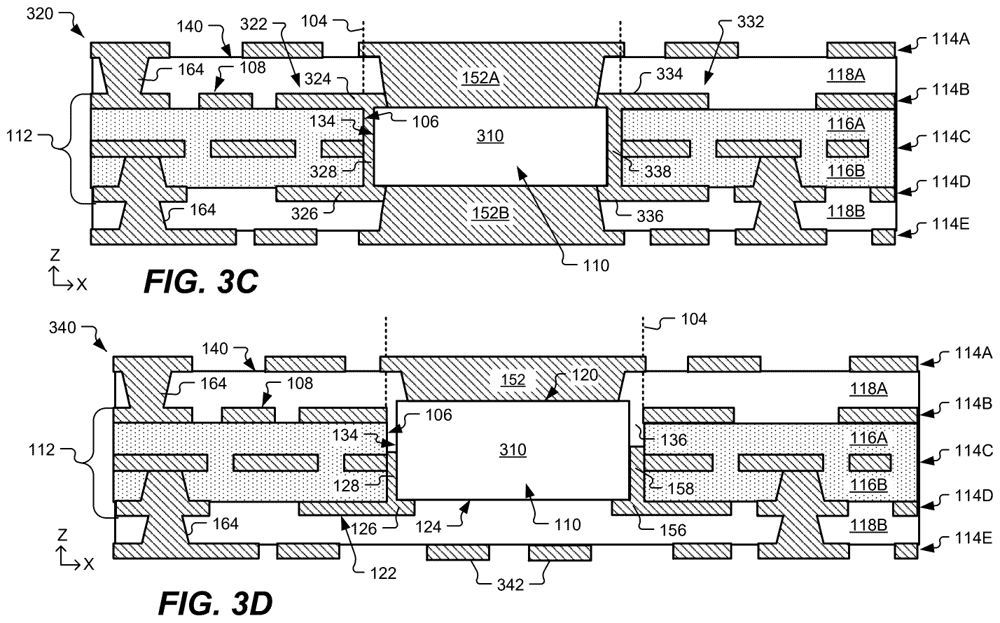

One or more components 110 are disposed within the embedding region 104. For example, in FIG. 1A, the component(s) 110 include the component 110A and the component 110B. In other examples, a single component 110 is disposed in the embedding region 104, and in still other examples, more than two components 110 are disposed in the embedding region 104. The type(s) of the component(s) 110, the arrangement of the components 110 in the embedding region 104, interconnections among the component(s) 110, or combinations of these and other characteristics of the component(s) 110 can vary between embodiments. For example, in FIG. 1A, the component(s) 110 include inductors. However, in other embodiments, the component(s) 110 can include capacitors, active components (e.g., components that include transistors), resistors, heat sinks, or other types of components. To illustrate, FIGS. 3A-3C depict examples in which the component(s) 110 include a heat sink. As used herein, a “heat sink” refers to a component configured to facilitate removal of heat from another component. A heat sink may include, for example, a metal structure (e.g., a copper block) that is configured to receive heat from a hotter component, and configured to temporarily store the heat for later release and/or to transfer the heat to another component or to a fluid. Thus, a heat sink can include a heat transfer component, a heat reservoir, or both.

The substrate 102 also includes PID layers 118 coupled to top and bottom surfaces of the multilayer dielectric-metal structure 112. For example, a PID layer 118A is coupled to a surface 108 (e.g., a top surface in the orientation illustrated in FIG. 1A) of the multilayer dielectric-metal structure 112, and a PID layer 118B is coupled to a surface 122 (e.g., a bottom surface in the orientation illustrated in FIG. 1A) of the multilayer dielectric-metal structure 112. For example, the surface 108 can include or correspond to a top surface of the metal layer 114B and portions of a top surface of the dielectric layer 116A. Similarly, the surface 122 can include or correspond to a bottom surface of the metal layer 114D and portions of a bottom surface of the dielectric layer 116B. The PID layers 118 are also coupled to the component(s) 110 within the embedding region 104. For example, the PID layer 118A is coupled to a surface 120 (e.g., a top surface in the orientation illustrated in FIG. 1A) of each of the component(s) 110, and the PID layer 118B is coupled to a surface 124 (e.g., a bottom surface in the orientation illustrated in FIG. 1A) of each of the component(s) 110. In some embodiments, the substrate 102 also includes a portion 136 of a PID layer disposed within the embedding region 104 in contact with at least one sidewall of one of the component(s) 110 (e.g., the component 110B in FIG. 1A) and in contact with at least one of the one or more sidewall(s) 106 of the multilayer dielectric-metal structure 112.

The substrate 102 can also include one or more additional metal layers 114 (e.g., metal layers 114A and 114E), one or more additional PID layers 118, one or more additional dielectric layers 116, or combinations thereof. For example, in FIG. 1A, a metal layer 114A is disposed on a surface 140 of the PID layer 118A, and a metal layer 114E is disposed on a surface 166 of the PID layer 118B. Conductive vias 164 can extend through the PID layer(s) 118, the dielectric layers 116, or both, to electrically couple two or more of the metal layers 114.

In a particular aspect, the substrate 102 includes a metal structure 126 that includes a portion 128 in contact with at least one of the sidewall(s) 106 of the multilayer dielectric-metal structure 112 and in contact with at least one sidewall 134 of one of the component(s) 110 (e.g., the component 110A in FIG. 1A). The portion 128 of the metal structure 126 electrically couples the component 110A and one or more metal lines of the multilayer dielectric-metal structure 112. For example, in FIG. 1A, the portion 128 of the metal structure 126 electrically couples the component 110A to one or more metal lines of the metal layer 114C.

In some embodiments, the substrate 102 includes one or more additional metal structures that include portion(s) in contact with other sidewall(s) of the same component (e.g., the component 110A in FIG. 1A), or with at least one sidewall of another component (e.g., the component 110B in FIG. 1A). For example, in FIG. 1A, the substrate 102 includes a metal structure 156 that includes a portion 158. In this example, the portion 158 of the metal structure 156 is in contact with at least one of the sidewall(s) 106 of the multilayer dielectric-metal structure 112 and is in contact with at least one sidewall of the component 110B. To illustrate, the portion 158 of the metal structure 156 may electrically couple the component 110B to one or more metal lines of the metal layer 114C.

As another example, in FIG. 1A, the substrate 102 also includes a metal structure 154 that includes a portion 162. In this example, the portion 162 of the metal structure 154 is in contact with at least one sidewall of the component 110A and at least one sidewall of the component 110B. To illustrate, the portion 162 of the metal structure 154 may electrically couple the component 110A to the component 110B. In this illustrative example, an electrical connection between the components 110 formed by the portion 162 of the metal structure 154 enables the components 110 to operate together. For example, the component 110A can include a first inductor device including one or more coils oriented along a coil axis and the component 110B can include a second inductor device including one or more coils oriented along the coil axis. In this example, the electrical connection between the inductor devices (e.g., the components 110A and 110B) enables the inductor devices to provide a larger inductance than either of the inductor devices individually.

One advantage of providing electrical connections between the substrate 102 and one or more of the component(s) 110 along sidewalls of the component(s) 110 and sidewall(s) of the multilayer dielectric-metal structure 112 is that metal layers 114 directly above or below the component(s) 110 can be patterned to include traces, contacts, or other conductive features, because electrical connections to the component(s) 110 do not rely on conductive vias electrically coupled directly to the top or bottom of the component(s) 110. For example, in FIGS. 1A and 1B, the substrate 102 includes one or more traces 130 that are directly above or directly below the component(s) 110 in a closest metal layer of the substrate 102 to the component(s) 110. As another example, in FIGS. 1A and 1B, the substrate 102 includes contacts 132 (e.g., a contact 132A and a contact 132B) that are positioned above the embedding region 104 of the substrate 102. The ability to provide contacts, traces, or both, directly above or below the component(s) 110 increases the routing options available for substrate designers and reduces package size by reducing lateral and/or vertical dimensions of the substrate 102 as compared to other substrates that include embedded components with electrical connections positioned above or below the electrical components.

Another advantage of the disclosed embodiments when the embedded component(s) 110 include an inductor device is reduction of lateral dimensions of the substrate 102 as compared to substrates in which an inductor is formed by coils patterned in one or more metal layers. A further advantage is that a coil axis of the inductor device can be oriented laterally (e.g., along the XY-plane of FIGS. 1A and 1B), rather than vertically (e.g., along the Z-axis of FIG. 1A), which enables omission of a ground plane. Omission of the ground plane reduces the thickness of the substrate 102. Further, when the coil axis of the inductor device is oriented laterally, a smaller inductor device can be used to provide the same inductance as an inductor device with a coil axis oriented vertically since the magnetic field flux of the laterally oriented inductor device is not cut off by the ground plane.

Although the device 100, as illustrated in FIG. 1A, includes the substrate 102 and the integrated device 160, in some embodiments, the device 100 includes more than one die, other components (e.g., passive electronic components), or both, coupled to the substrate 102. Further, in some embodiments, the device 100 includes other components, features, or configurations. For example, the substrate 102 can be electrically coupled to one or more other substrates in a package-on-package configuration. As another example, in some embodiments, the device 100 includes mold compound at least partially encapsulating the integrated device 160, includes a lid coupled to the substrate 102 and covering at least a portion of the integrated device 160, etc.

The integrated device(s) 160 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

In embodiments in which the device 100 includes more than one integrated device 160, the integrated devices 160 can be arranged and interconnected as a three-dimensional (3D) IC device. In some implementations, one or more of the dies include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the device 100. Additionally, or alternatively, one or more of the dies may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

It should be understood that the device 100 may include additional components, other components, fewer components, or a combination thereof, to support the functionality described herein. As non-limiting examples, the device 100 may include additional dies, additional substrates, additional layers, additional packages, additional interconnects, additional structures, other components, different components, or a combination thereof, to support the functionality and technical advantages disclosed herein.

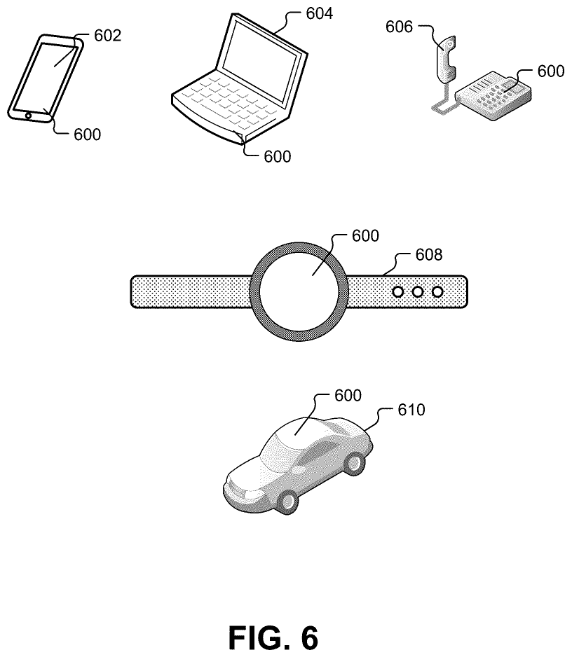

Although the device 100 is shown by itself in FIG. 1A, it should be understood that the device 100 can be interconnected with or integrated within one or more other devices in a package, a system, or an electronic device without departing from the scope of the subject disclosure. For example, a device that includes the device 100 as a component can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the device 100 can operate as any of these components (or a combination of these components) that includes active circuitry. To illustrate, the device 100 can be integrated in a smartphone, a tablet computer, a fixed location terminal device, an automobile, a wearable electronic device, a laptop computer, or some combination thereof, as described in more detail below with reference to FIG. 6.

In a particular implementation, the device 100 includes an integrated device 160 (e.g., one or more dies) and a substrate (e.g., the substrate 102) electrically coupled to the integrated device. In this implementation, the substrate includes a multilayer dielectric-metal structure (e.g., the multilayer dielectric-metal structure 112) including one or more sidewalls (e.g., the sidewall(s) 106) defining an embedding region (e.g., the embedding region 104) within the multilayer dielectric-metal structure. In this implementation, the multilayer dielectric-metal structure includes first metal layers (e.g., metal layers 114B, 114C, and 114D) patterned to define first metal lines, and first dielectric layers (e.g., the dielectric layers 116A and 116B) intermingled with the first metal lines. The substrate also includes a first component (e.g., one of the component(s) 110, such as the component 110A and/or the component 110B) disposed within the embedding region. The substrate also includes a first PID layer (e.g., the PID layer 118A) coupled to a first surface (e.g., the surface 108) of the multilayer dielectric-metal structure and to a first surface (e.g., the surface 120) of the first component, where the first surface of the multilayer dielectric-metal structure is adjacent to the one or more sidewalls of the multilayer dielectric-metal structure. The substrate also includes a second PID layer (e.g., the PID layer 118B) coupled to a second surface (e.g., the surface 122) of the multilayer dielectric-metal structure and to a second surface (e.g., the surface 124) of the first component, where the second surface of the multilayer dielectric-metal structure is adjacent to the one or more sidewalls of the multilayer dielectric-metal structure and is opposite the first surface of the multilayer dielectric-metal structure. The substrate also includes a first metal structure (e.g., the metal structure 126) including a portion (e.g., the portion 128) in contact with at least one of the one or more sidewalls (e.g., one of the sidewall(s) 106) of the multilayer dielectric-metal structure and at least one sidewall (e.g., one of the sidewall(s) 134) of the first component, where the portion of the first metal structure is electrically coupled to the first component and the first metal lines (e.g., a metal line of the metal layer 114C).

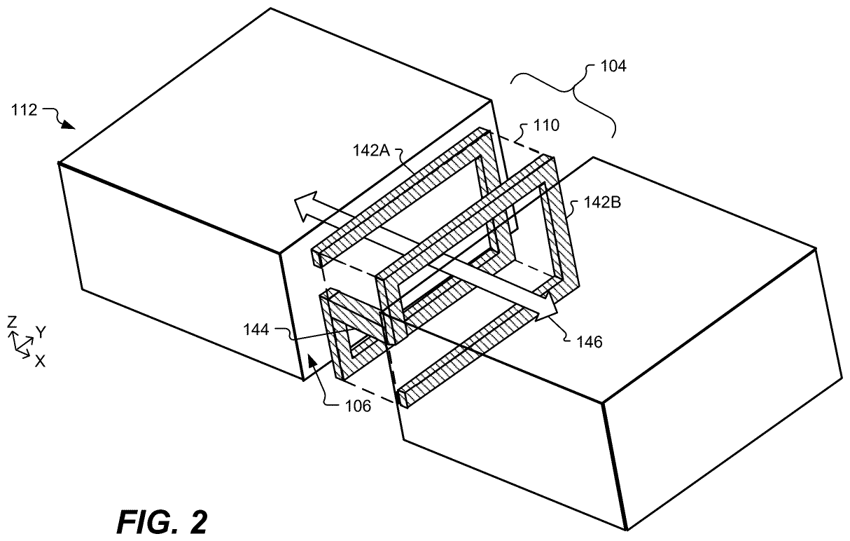

FIG. 2 illustrates a schematic perspective view of a portion of the multilayer dielectric-metal structure 112 of FIG. 1A. FIG. 2 also illustrates an example of a component 110 disposed within an embedding region 104 defined by one or more sidewalls 106 of the multilayer dielectric-metal structure 112. In FIG. 2, the component 110 is illustrated as an inductor device. For example, component 110 includes a plurality of coils 142 (e.g., a coil 142A and a coil 142B) that are electrically coupled to one another by an interconnect 144.

The coils 142 of the inductor device of FIG. 2 are arranged such that a coil axis 146 of the coils 142 is oriented laterally (e.g., substantially within a plane defined by the X-and Y-axes in FIG. 2 or substantially parallel with respect to a normal of at least one of the one or more sidewalls 106 of the multilayer dielectric-metal structure 112). One advantage of this lateral orientation of the inductor device is that a substrate that includes the multilayer dielectric-metal structure 112 with the inductor device does not need a ground plane as shield for magnetic flux of the inductor device. As a result, the magnetic flux is not cut off early, leading to better inductor performance (e.g., higher inductance for the same size or smaller coil aperture). Another advantage is that the inductor device can be formed using distinct processes from formation of metal layers of the substrate. As a result, a thickness of the metal lines used to form the coils 142 is not limited to the same thickness as other lines of the substrate. For example, the metal lines used to form the coils 142 can be thicker, which provides greater current carrying capacity.

FIG. 3A illustrates a schematic cross-sectional profile view of another exemplary device 300. FIG. 3B illustrates a schematic top view of a portion of a substrate 302 of the device 300 with the integrated device 160 omitted. In particular, FIG. 3B shows a surface 140 of the substrate 302 in an area around an embedding region 104 of the substrate 302. FIG. 3B also shows a cutline AA associated with the cross-sectional profile view of FIG. 3A.

The device 300 is similar to the device 100 of FIGS. 1A and 1B and includes many of the same features, which are associated with the same reference numbers as in FIG. 1A. For example, the device 300 includes the integrated device 160 electrically coupled to the substrate 302. The substrate 302 includes the multilayer dielectric-metal structure 112, which includes multiple dielectric layers 116 arranged with respect to the multiple metal layers 114. The metal layers 114 can be interconnected at various locations by conductive vias 164. Further, sidewall(s) 106 of the multilayer dielectric-metal structure 112 define the embedding region 104. The substrate 302 also includes the PID layer(s) 118 and additional metal layers 114A and 114E.

In contrast to the device 100 of FIGS. 1A and 1B, in the device 300 of FIGS. 3A and 3B, the component(s) 110 disposed within the embedding region 104 of the multilayer dielectric-metal structure 112 of the substrate 302 include or correspond to a heat sink 310. For example, the heat sink 310 can include or correspond to a solid mass of copper or another thermally conductive metal.

Although FIGS. 3A and 3B show a single heat sink 310 in the embedding region 104, in other examples, one or more additional components 110 can be disposed in the embedding region 104 with the heat sink 310. To illustrate, the substrate 302 can include the heat sink 310 as well as one or more additional heat sinks, one or more additional electronic components (e.g., inductors, capacitors, resistors), or a combination thereof.

In a particular aspect, the substrate 302 includes the metal structure 126 that includes the portion 128 in contact with at least one of the sidewall(s) 106 of the multilayer dielectric-metal structure 112 and in contact with at least one sidewall 134 of one of the heat sink(s) 310. The portion 128 of the metal structure 126 electrically couples the heat sink 310 and one or more metal lines of the multilayer dielectric-metal structure 112. For example, in FIG. 3A, the portion 128 of the metal structure 126 electrically couples the heat sink 310 to one or more metal lines of the metal layer 114C. To illustrate, the metal layer 114C can provide a ground connection for the heat sink 310.

In some embodiments, the substrate 302 includes one or more additional metal structures that include portion(s) in contact with other sidewall(s) of the same component (e.g., the heat sink 310 in FIG. 3A), or with at least one sidewall of another component. For example, in FIG. 3A, the substrate 302 includes the metal structure 156 that includes the portion 158. In this example, the portion 158 of the metal structure 156 is in contact with at least one of the sidewall(s) 106 of the multilayer dielectric-metal structure 112 and is in contact with at least one sidewall of the heat sink 310. To illustrate, the portion 158 of the metal structure 156 may electrically couple the heat sink 310 to one or more metal lines of the metal layer 114C. In examples in which two or more components 110 are embedded in the substrate 302, the substrate 302 can also include the metal structure 154 as shown in FIG. 1A that includes the portion 162 electrically coupling the two or more components 110.

The heat sink 310 can be thermally coupled by vias 152 (e.g., a via 152A and a via 152B) to surfaces of the substrate 302. For example, the via 152A provides a thermal conduction path between the heat sink 310 and the surface 140 of the substrate 302, and the via 152B provides a thermal conduction path between the heat sink 310 and the surface 166 of the substrate 302. The large thermal conduction paths provided by the combination of the vias 152 and the heat sink 310 can provide significant capacity to remove heat from the integrated device 160.

Although the device 300, as illustrated in FIG. 3A, includes the substrate 302 and the integrated device 160, in some embodiments, the device 300 includes more than one die, other components (e.g., passive electronic components), or both, coupled to the substrate 302. Further, in some embodiments, the device 300 includes other components, features, or configurations. For example, the substrate 302 can be electrically coupled to one or more other substrates in a package-on-package configuration. As another example, in some embodiments, the device 300 includes mold compound at least partially encapsulating the integrated device 160, includes a lid coupled to the substrate 302 and covering at least a portion of the integrated device 160, etc.

FIGS. 3C and 3D illustrate schematic perspective views of other examples of substrates that include embedded components. In particular, FIG. 3C illustrates an example of a substrate 320 that includes a metal structure 322 with a portion 324 on a first side of the multilayer dielectric-metal structure 112, a portion 326 on a second side of the multilayer dielectric-metal structure 112, and a portion 328 disposed between and coupled to each of the other portions 324, 326 of the metal structure 332. The portion 328 is in contact with at least one of the sidewall(s) 106 of the multilayer dielectric-metal structure 112 and in contact with at least one sidewall 134 of one of the component(s) 110. The portion 328 of the metal structure 322 electrically couples the component(s) 110 and one or more metal lines of the multilayer dielectric-metal structure 112.

In some embodiments, the substrate 320 also includes one or more additional metal structures that include portion(s) in contact with other sidewall(s) 134 of the same component, or with at least one sidewall 134 of another component. For example, in FIG. 3C, the substrate 320 includes a metal structure 332 that includes a portion 334 on the first side of the multilayer dielectric-metal structure 112, a portion 336 on the second side of the multilayer dielectric-metal structure 112, and a portion 338 disposed between and coupled to each of the other portions 334, 336 of the metal structure 332. The portion 338 is in contact with at least one of the sidewall(s) 106 of the multilayer dielectric-metal structure 112 and in contact with at least one sidewall 134 of one of the component(s) 110. The portion 338 of the metal structure 322 electrically couples the component(s) 110 and one or more metal lines of the multilayer dielectric-metal structure 112.

FIG. 3D illustrates an example of a substrate 340 in which the heat sink 310 can be thermally coupled by a via(s) 152 to a single surface of the substrate 340. For example, the via 152 can correspond to or include the via 152A of FIG. 3A or the via 152B of FIG. 3A. In the example illustrated in FIG. 3D, conductive feature(s) 342 can be formed on a metal layer 114 closest to the heat sink 310 on a side opposite the via(s) 152, which provide more options for routing and electrical connections to the substrate 340 as compared to the substrate 302 of FIG. 3A or the substrate 320 of FIG. 3C. Although the substrate 340 of FIG. 3D is illustrated as including the metal structures 126 and 156, in other examples, the substrate 340 can include the metal structures 322 and 332, as described with reference to FIG. 3C.

### Exemplary Sequence for Fabricating a Substrate with One or More Embedded Components or a Device including the Substrate

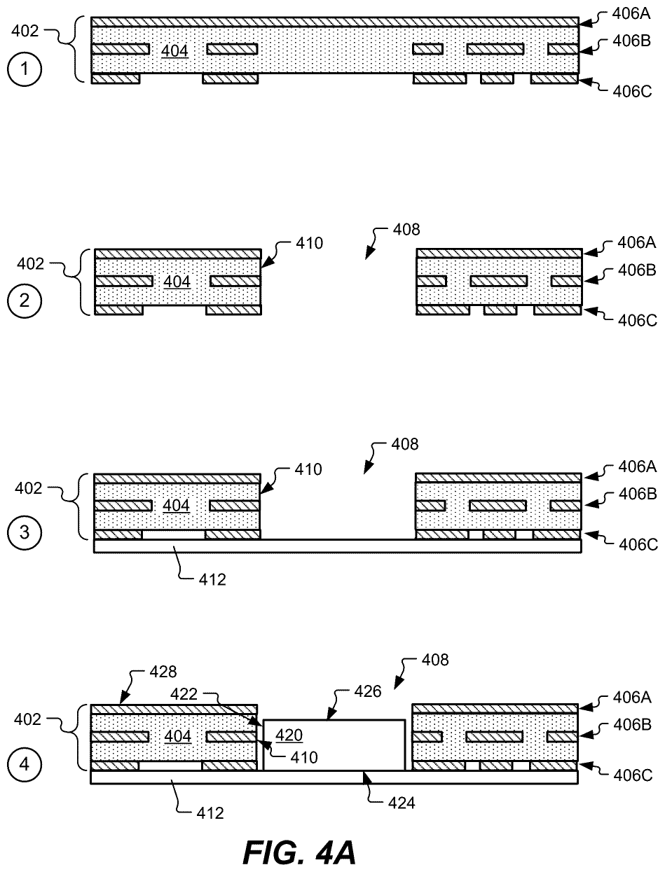

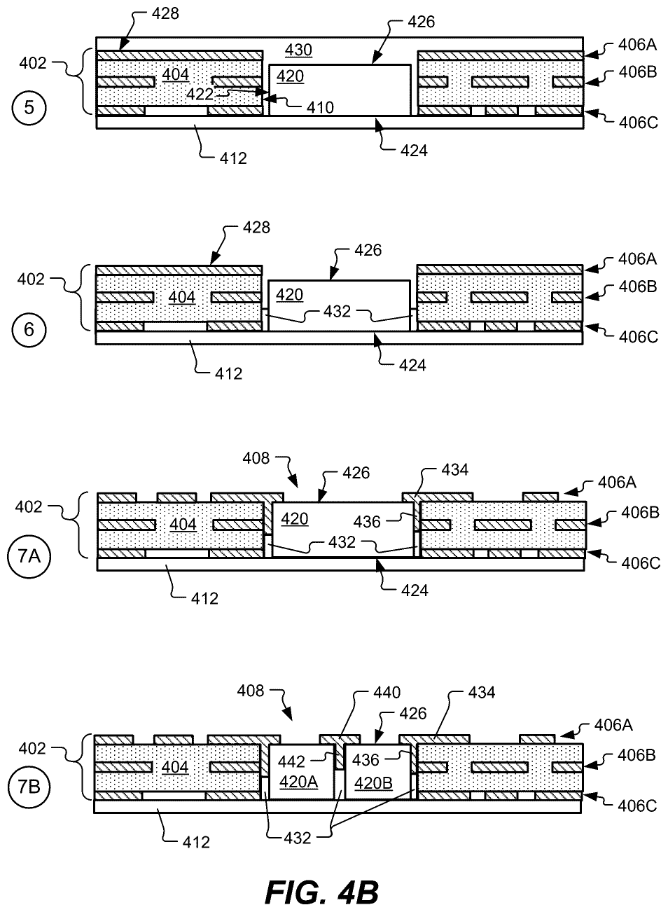

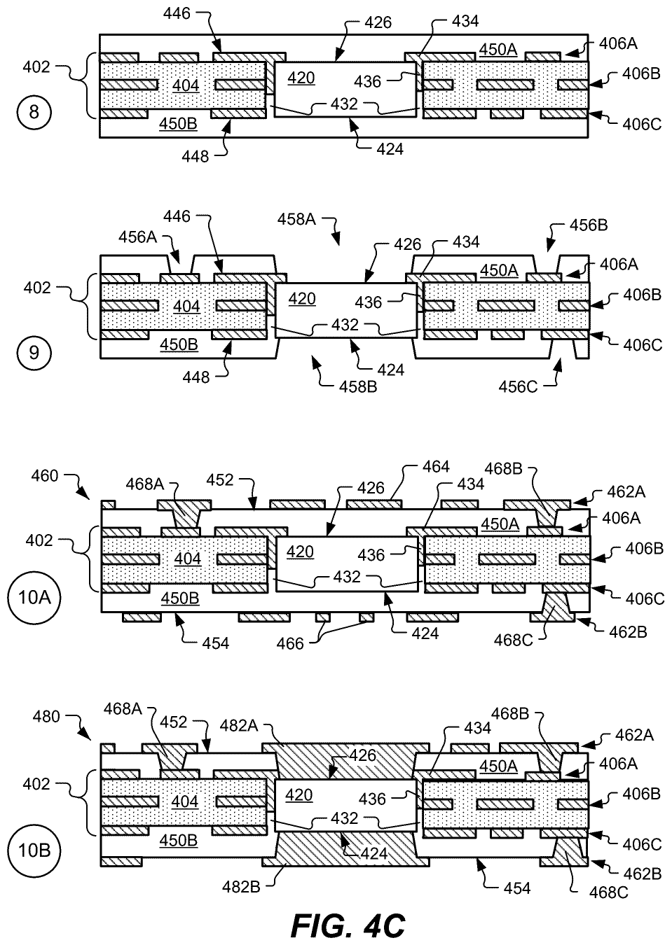

In some implementations, fabricating a substrate with one or more embedded components (e.g., any of the substrates 102, 302, 320 or 340) or a device (e.g., the device 100 or the device 300) that includes the substrate includes several processes. FIGS. 4A-4C illustrate an exemplary sequence for fabricating or providing a substrate with one or more embedded components, as described with reference to any of FIGS. 1A-3D. In some implementations, the sequence of FIGS. 4A-4C may be used to provide (e.g., during fabrication of) the substrate 102 or the device 100 of FIG. 1A, the device 300 or the substrate 302 of FIG. 3A, the substrate 320 of FIG. 3C, or the substrate 340 of FIG. 3D.

It should be noted that the sequence of FIGS. 4A-4C may combine one or more stages in order to simplify and/or clarify the sequence for providing or fabricating a substrate with one or more embedded components. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 4A-4C. Each of the various stages of the sequence illustrated in FIGS. 4A-4C shows a single substrate being formed. In other implementations, multiple substrates may be formed concurrently (e.g., by performing the operations described at a strip level or a panel level).

Stage 1 of FIG. 4A illustrates a state after formation of a multilayer dielectric-metal structure 402 that includes a plurality of metal layers 406 (e.g., a metal layer 406A, a metal layer 406B, and a metal layer 406C) interspersed among one or more dielectric layers 404. In the example illustrated in FIG. 4A, the metal layers 406B and 406C are patterned to form various conductive features, such as traces, via pads, etc., and the metal layer 406A is not patterned at Stage 1. In other examples, the metal layer 406A is patterned at Stage 1, and in still other examples, the metal layer 406C is not patterned at Stage 1. Although the multilayer dielectric-metal structure 402 of FIG. 4A is illustrated with three metal layers 406, in other examples, the multilayer dielectric-metal structure 402 can include more than three metal layers 406 or fewer than three metal layers (e.g., two metal layers).

The multilayer dielectric-metal structure 402 can be formed using lamination techniques and patterning techniques. For example, the metal layer 406C can be formed on (e.g., deposited on) or applied to (e.g., as a film) a carrier substrate. In this example, a dielectric material can be formed on or applied to the metal layer 406C to form one of the dielectric layer(s) 404, and the metal layer 406B can be formed on or applied to the dielectric layer. These steps can be repeated until the multilayer dielectric-metal structure 402 has the desired number and arrangement of layers. In some cases, a metal layer 406 can be patterned before it is covered by a dielectric material. In this example, the multilayer dielectric-metal structure 402 can be removed from the carrier substrate after formation. Alternatively, the carrier substrate can remain coupled to the multilayer dielectric-metal structure 402 through one or more additional stages of a fabrication process, such as until Stage 2.

Stage 2 illustrates a state after an opening 408 is formed in the multilayer dielectric-metal structure 402. One or more sidewalls 410 of the multilayer dielectric-metal structure 402 define boundaries of the opening 408, which corresponds to an embedding region (e.g., the embedding region 104 of FIG. 1A) of the multilayer dielectric-metal structure 402. The opening 408 can be formed using physical and/or chemical processes. For example, the multilayer dielectric-metal structure 402 can be cut or drilled to form the opening 408. As another example, etching operations can be used to remove material of the multilayer dielectric-metal structure 402 to form the opening 408.

Stage 3 illustrates a state after tape 412 or another carrier substrate is attached to the multilayer dielectric-metal structure 402, and Stage 4 illustrates a state after one or more components 420 are positioned within the opening 408. The component(s) 420 are retained in a desired position within the opening 408 by adhesive in contact with a surface 424 of the component(s) 420. In a particular aspect, at least one sidewall 422 of the component(s) 420 is disposed adjacent to (but not in contact with) at least one sidewall 410 of the multilayer dielectric-metal structure 402. In the example illustrated in FIG. 4A, a height of the component(s) 420 is less than a height of the multilayer dielectric-metal structure 402 resulting in an upper surface 426 (in the orientation illustrated) of the component(s) 420 sitting below a surface 428 of the multilayer dielectric-metal structure 402. In other examples, the height of the component(s) 420 is substantially equal to (or slightly greater than) the height of the multilayer dielectric-metal structure 402.

Stage 5 of FIG. 4B illustrates a state after a PID layer 430 is formed on the surface 428 of the multilayer dielectric-metal structure 402, on the surface 426 of the component(s) 420, and in a gap between the sidewall(s) 410 of the multilayer dielectric-metal structure 402 and the sidewall(s) 422 of the component(s) 420. For example, the PID layer 430 can be applied using a dry film process. Alternatively, in some cases, a liquid or gel PID material can be applied to the multilayer dielectric-metal structure 402 to form the PID layer 430.

Stage 6 illustrates a state after patterning of the PID layer 430 to form portions 432 of cured PID in the gap between the sidewall(s) 410 of the multilayer dielectric-metal structure 402 and the sidewall(s) 422 of the component(s) 420. For example, the PID material of the PID layer 430 can be selectively exposed to light and subsequently exposed to developer (e.g., a chemical bath). Exposure to the developer can be timed to develop the PID material through a partial thickness of the PID layer 430. As a result, after cleaning to remove undeveloped PID material, the portions 432 of the cured PID remain in the gap.

Stages 7A and 7B each illustrates a state after formation of one or more metal structures 434 that includes a portion 436 in contact with at least one of the sidewall(s) 410 (illustrated at Stage 5) of the multilayer dielectric-metal structure 402 and in contact with at least one sidewall 422 (illustrated at Stage 5) of one of the component(s) 420. The portion 436 of the metal structure 434 electrically couples the component 420 and one or more metal lines of the multilayer dielectric-metal structure 402. For example, in FIG. 4B, the portion 436 of the metal structure 434 electrically couples the component 420 to one or more metal lines of the metal layer 406B.

Stage 7A and 7B illustrate alternative examples of states after additional operations are performed to form one or more metal structures. Stage 7A illustrates an example in which a single component 420 is disposed within the opening 408, and Stage 7B illustrates an alternative example in which more than one component 420 is disposed within the opening 408. For example, in the example illustrated at Stage 7B, two components 420 (including a component 420A and a component 420B) are disposed within the opening 408. Thus, the state illustrated at Stage 7B is after formation of the metal structure(s) 434 and after formation of one or more metal structures 440. The metal structure(s) 440 include a portion 442 that is in contact with facing sidewalls of two of the components 420. For example, in FIG. 4B at Stage 7B, the portion 442 is in contact with, and electrically couples, a sidewall of the component 420A and a sidewall of the component 420B.

In some embodiments, the metal structure(s) 434 and the metal structure(s) 440 (if present) can be formed at the same time. For example, metal deposition techniques, such as plating, printing, etc. can be used to form the metal structure(s) 434 and the metal structure(s) 440 in parallel. Depending on the specific metal deposition technique used, the process may be guided by a patterned photoresist layer. In other embodiments, the metal structure(s) 434 and the metal structure(s) 440 can be formed sequentially.

If the metal layer 406A was not previously patterned (e.g., at one of Stages 1-6), the metal layer 406A can be patterned at Stage 7A or 7B. In some embodiments, the metal layer 406A can be omitted from the multilayer dielectric-metal structure 402 in each of Stage 1-6 and formed along with the metal structure(s) 434 and the metal structure(s) 440 (if present) at Stage 7A or 7B.

Stage 8 of FIG. 4C illustrates a state after the multilayer dielectric-metal structure 402 is detached from the tape 412, and one or more PID layers 450 are formed on the multilayer dielectric-metal structure 402. For example, in FIG. 4C, a PID layer 450A is formed on a surface 446 of the multilayer dielectric-metal structure 402 and a surface 426 of the component(s) 420. Similarly, a PID layer 450B is formed on a surface 448 of the multilayer dielectric-metal structure 402 and a surface 424 of the component(s) 420. The PID layer(s) 450 can be formed using similar operations to those described with reference to Stages 5 and 6. For example, a PID material can be applied as a dry film, as a liquid, or as a gel and developed to form the PID layer(s) 450.

Stage 9 of FIG. 4C illustrates a state after the one or more of the PID layer(s) 450 are patterned to form openings 456, 458. For example, the PID layer(s) 450 can be patterned via selective exposure to light and subsequent development. The openings 456 (e.g., opening 456A, opening 456B, and opening 456C) expose features of metal layers 406 below the PID layer(s) 450. For example, the openings 456A and 456B in the example illustrated in FIG. 4C expose via pads formed in the metal layer 406A, and the opening 456C exposes a via pad formed in the metal layer 406C. The number and location of the metal layer(s) 406 exposed by the openings 456 are merely exemplary. In other examples, the PID layer(s) 450 can be patterned to form more openings 456, fewer openings 456, openings that exposed features of different metal layers (e.g., the metal layer 406B), openings 456 at different positions, or combinations thereof.

The openings 458 (including opening 458A and opening 458B) are optional. In some examples, the opening 458A, the opening 458B, or both, are not formed. For example, during formation of the substrate 102 of FIG. 1A, neither of the openings 458 is formed. As another example, during formation of the substrate 340 of FIG. 3D, the opening 458A is formed, and the opening 458B is not formed. The opening 458A (if formed) exposes a portion of the surface 426 of the component(s) 420, and the opening 458B (if formed) exposes a portion of the surface 424 of the component(s) 420.

Stages 10A and 10B illustrate alternative examples of states after additional operations are performed to form a completed substrate. For example, Stage 10A illustrates a state after completion of a substrate 460, and Stage 10B illustrates a state after completion of a substrate 480. Completion of each of the substrates 460, 480 includes forming conductive features in one or more of the openings 456 and 458 (if present), and formation of one or more metal layers 462. Optionally, in some examples, one or more additional dielectric layers and one or more additional metal layers can also be formed.

The example of Stage 10A illustrates a state after formation of one or more vias 468 and metal layer(s) 462. For example, the vias 468 include a via 468A within the opening 456A of Stage 9, a via 468B within the opening 456B, and a via 468C within the opening 456C. Further, in this example, the metal layer(s) 462 include a metal layer 462A on a surface 452 of the PID layer 450A, and a metal layer 462B on a surface 454 of the PID layer 450B. The via(s) 468 and metal layer(s) 462 can be formed using one or more metal deposition processes, such as plating, physical vapor deposition, chemical vapor deposition, printing, etc., which may be guided by one or more patterned photoresist layer (not shown). The via(s) 468 and metal layer(s) 462 can be formed sequentially or at least partially in parallel.

The example of Stage 10B illustrates a state after formation of one or more vias 468, one or more metal structures 482, and one or more metal layer(s) 462. Like Stage 10A, the vias 468 include a via 468A within the opening 456A of Stage 9, a via 468B within the opening 456B, and a via 468C within the opening 456C. Further, the metal layer(s) 462 include a metal layer 462A on a surface 452 of the PID layer 450A, and a metal layer 462B on a surface 454 of the PID layer 450B. The metal structure(s) 482 include a metal structure 482A within the opening 458A of Stage 9, a metal structure 482B within the opening 458B, or both. The via(s) 468, the metal structure(s) 482, and metal layer(s) 462 can be formed using one or more metal deposition processes, such as plating, physical vapor deposition, chemical vapor deposition, printing, etc., which may be guided by one or more patterned photoresist layer (not shown). The via(s) 468, the metal structure(s) 482, and metal layer(s) 462 can be formed sequentially or at least partially in parallel.

In some examples, the substrate 460, the substrate 480, or both, can include one or more conductive features (e.g., contacts, pads, traces, etc.) in a closest metal layer above or below the component(s) 420. For example, as shown at Stage 10A, the metal layer 462A is the closest metal layer above the component(s) 420 and includes a conductive feature 464 above the component(s) 420. As another example, as shown at Stage 10A, the metal layer 462B is the closest metal layer below the component(s) 420 and includes conductive features 466 below the component(s) 420.

The substrate 460 is an example of the substrate 102 of FIGS. 1A and 1B. For example, component(s) 420 of substrate 460 are examples of (e.g., correspond to or include) the component(s) 110 of the substrate 102. Further, the multilayer dielectric-metal structure 402 is an example of the multilayer dielectric-metal structure 112, the PID layer(s) 450 are examples of the PID layer(s) 118, the metal structure(s) 434 are examples of the metal structure 126, 156, or both, the via(s) 468 are examples of the via(s) 164, and the conductive feature(s) 464, 466, or both, are examples of the trace(s) 130, the contact(s) 132, or both.

The substrate 480 is an example of the substrate 302 of FIGS. 3A and 3B. For example, component(s) 420 of substrate 460 are examples of (e.g., correspond to or include) the heat sink 310 of the substrate 302. Further, the multilayer dielectric-metal structure 402 is an example of the multilayer dielectric-metal structure 112, the PID layer(s) 450 are examples of the PID layer(s) 118, the metal structure(s) 434 are examples of the metal structure 126, 156, or both, the via(s) 468 are examples of the via(s) 164, and the conductive feature(s) 464, 466, or both, are examples of the trace(s) 130, the contact(s) 132, or both.

In some examples, the operations described above can be used to form the substrate 340 of FIG. 3D. For example, when forming an instance of the substrate 340, formation of the opening 458A can be omitted at Stage 9 of FIG. 4A. In this example, the via(s) 152 of FIG. 3D can be formed as described with reference to Stage 10B on a side of the heat sink 310 opposite the metal structures 126, 156. In this example, the metal layer 114E can be formed on the PID layer 118B as described with reference to formation of the metal layer 462A at Stage 10A.

In some examples, the operations described above can be modified to form the substrate 320 of FIG. 3C. For example, when forming an instance of the substrate 320, after formation of the metal structure(s) 434, on a first side of the multilayer dielectric-metal structure 402 at Stage 7A or 7B, the tape 412 can be removed, the portions 432 of the cured PID in the gap between the sidewall(s) 410 of the multilayer dielectric-metal structure 402 and the sidewall(s) 422 of the component(s) 420 can be removed (e.g., by etching or another chemical or physical process), and additional metal structures 434 can be formed on a second side of the multilayer dielectric-metal structure 402. In some examples, an additional tape layer can be applied to the first side of the multilayer dielectric-metal structure 402 before formation of the additional metal structures 434 on the second side of the multilayer dielectric-metal structure 402 (e.g., before removal of the tape 412). After the additional metal structures 434 on the second side of the multilayer dielectric-metal structure 402, operations to form the substrate 320 proceed as described above with reference to formation of the substrate 480 of FIG. 4C.

Formation of a substrate is complete after Stage 10 (e.g., formation of the substrate 480 is complete at Stage 10A, and formation of the substrate 480 is complete after Stage 10B). One or more integrated devices 160 (e.g., die(s) and/or other components) can be attached to the substrate to form a device (e.g., the device 100 of FIG. 1A or the device 300 of FIG. 3A).

### Exemplary Flow Diagram of a Method for Fabricating a Device Including a Substrate with One or More Embedded Components

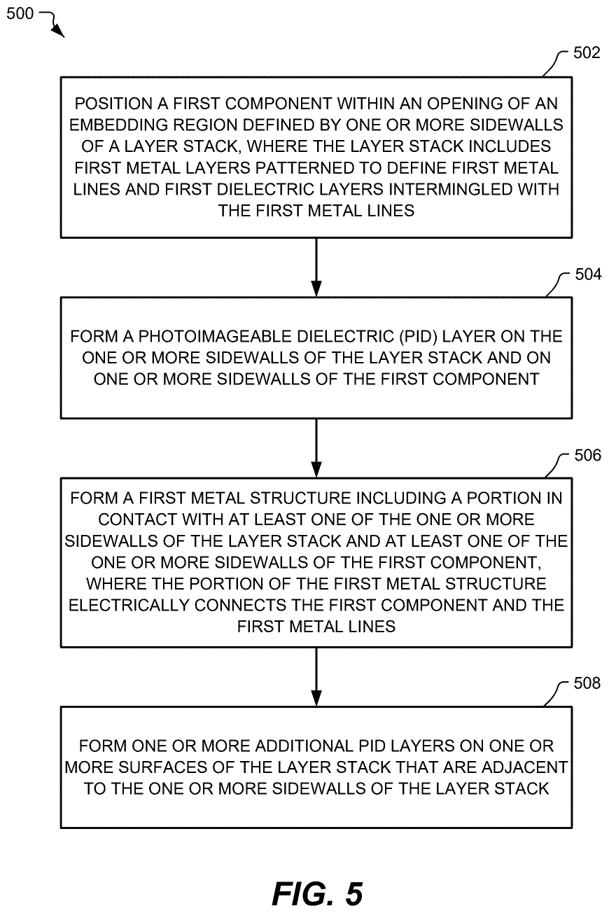

In some implementations, fabricating a substrate with one or more embedded components (e.g., any of the substrates 102, 302, 320 or 340) or a device (e.g., the device 100 or the device 300) that includes the substrate includes several processes. FIG. 5 illustrates an exemplary flow diagram of a method 500 of fabricating a substrate with one or more embedded components, as described with reference to any of FIGS. 1A-4C. In some implementations, the method 500 may be used to provide (e.g., during fabrication of) the substrate 102 or the device 100 of FIG. 1A, the device 300 or the substrate 302 of FIG. 3A, the substrate 320 of FIG. 3C, the substrate 340 of FIG. 3D, the substrate 460 of FIG. 4C, or the substrate 480 of FIG. 4C. In a particular aspect, one or more operations of the method 500 are performed by one or more processors of a fabrication system. In some implementations, operations of the method 500 may be stored as instructions by a non-transitory computer-readable storage medium, and the instructions may be executable by at least one processor to cause the at least one processor to perform operations of the method 500.

It should be noted that the method 500 of FIG. 5 may combine one or more processes in order to simplify and/or clarify the method for providing or fabricating an integrated circuit device. In some implementations, the order of the processes may be changed or modified.

The method 500 includes, at block 502, positioning a first component within an opening of an embedding region defined by one or more sidewalls of a multilayer dielectric-metal structure, where the multilayer dielectric-metal structure includes first metal layers patterned to define first metal lines and first dielectric layers among or arranged with respect to the first metal lines. For example, the first component can include or correspond to one of the component(s) 110 of FIG. 1A, the component 110 of FIG. 2, the heat sink of 310 FIG. 3A, FIG. 3C, or FIG. 3D, or the component(s) 420 of FIGS. 4A-4C. In various examples, the first component can include one or more inductors, one or more capacitors, one or more active components (e.g., components that include transistors), one or more resistors, one or more heat sinks, or one or more other types of components.

The multilayer dielectric-metal structure can include or correspond to the multilayer dielectric-metal structure 112 of any of FIGS. 1A, 2, 3A, 3C, 3D, or 4A-4C. For example, the multilayer dielectric-metal structure can include the dielectric layer(s) 116 and the metal layer(s) 114 of any of FIGS. 1A, 2, 3A, 3C, or 3D. The metal layer(s) 114 are patterned to define metal lines, and dielectric layer(s) 116 are intermingled with the metal lines. As another example, the multilayer dielectric-metal structure can include the dielectric layer(s) 404 and the metal layer(s) 406 of any of FIGS. 4A-4C. The metal layer(s) 406 are patterned to define metal lines, and dielectric layer(s) 404 are intermingled with the metal lines.

As described with reference to Stage 1 of FIG. 4A, the multilayer dielectric-metal structure can be formed using lamination techniques and patterning techniques. After the multilayer dielectric-metal structure is formed, one or more openings can be defined in the multilayer dielectric-metal structure, as described with reference to Stage 2 of FIG. 4A. In this example, sidewalls of the multilayer dielectric-metal structure correspond to sidewalls of the opening. After the opening is formed, the first component can be positioned in the opening as described with reference to Stages 3 and 4 of FIG. 4A.

The method 500 includes, at block 504, forming a PID layer on the one or more sidewalls of the multilayer dielectric-metal structure and on one or more sidewalls of the first component. For example, the PID layer can be formed using one or more deposition, exposure, and development operations, as described with reference to Stages 5 and 6 of FIG. 4B. The PID layer can correspond to or include the PID layer 430 of FIG. 4B prior to development, and correspond to the portions 136 of FIGS. 1A, 3A, or 3D or to the portions 432 of FIG. 4B subsequent to development.

The method 500 includes, at block 506, forming a first metal structure including a portion in contact with at least one of the one or more sidewalls of the multilayer dielectric-metal structure and at least one of the one or more sidewalls of the first component, where the portion of the first metal structure is electrically coupled to the first component and the first metal lines. For example, the first metal structure can correspond to or include one or more of the metal structures 126, 156 of any of FIGS. 1A, 3A, or 3D, one or more of the metal structures 322, 332 of FIG. 3C, or one or more of the metal structures 434 of FIG. 4B or 4C.

In examples in which multiple components (e.g., at least the first component and a second component) are disposed in the embedding region of the multilayer dielectric-metal structure, one or more additional metal structures can be formed (sequentially or in parallel with formation of the first metal structure). For example, a second metal structure can be formed that includes a portion in contact with at least one of the one or more sidewalls of the multilayer dielectric-metal structure and at least one sidewall of the second component, where the portion of the second metal structure electrically couples the second component and the first metal lines. To illustrate, when the first metal structure corresponds to the metal structure 126 of FIG. 1A, the second metal structure corresponds to the metal structure 156 of FIG. 1A.

Additionally, or alternatively, a third metal structure including a portion in contact with at least one sidewall of the first component and at least one sidewall of the second component can be formed. The portion of the third metal structure can electrically couple the first component and the second component. To illustrate, the third metal structure can correspond to or include the metal structure 154 of FIG. 1A.

The method 500 includes, at block 508, forming one or more additional PID layers on one or more surfaces of the multilayer dielectric-metal structure that are adjacent to the one or more sidewalls of the multilayer dielectric-metal structure. For example, the one or more additional PID layers can correspond to or include any of the PID layer(s) 118 of FIGS. 1A, 3A, 3C or 3D, or the PID layer(s) 450 of FIG. 4C. The PID layer(s) can be formed using one or more deposition, exposure, and development operations, as described with reference to Stages 8 and 9 of FIG. 4C.

In some embodiments, after formation of the one or more additional PID layers, the method can include additional operations to electrically couple an integrated device to the first component by way of the first metal structure. For example, the integrated device 160 can be coupled to a substrate that includes the multilayer dielectric-metal structure, the first component, the one or more additional PID layers, and one or more additional metal layers, using flip chip die attach operations.

In some examples, the first component includes an inductor device including one or more coils that define a coil axis. In such examples, the first component (including the inductor device) can be positioned in the opening of the multilayer dielectric-metal structure such that the coil axis is oriented along a first direction that is substantially parallel with respect to a normal of at least one of the one or more sidewalls of the multilayer dielectric-metal structure. For example, the coil axis can be oriented as described with respect to the coil axis 146 of FIG. 2.

### Exemplary Electronic Devices

FIG. 6 illustrates various electronic devices that may include or be integrated with any of the device 100 of FIG. 1A, the device 300 of FIG. 3A, or another device that includes a substrate with one or more embedded components (e.g., the substrate 102 of FIG. 1A, the substrate 302 of FIG. 3A, the substrate 320 of FIG. 3C, the substrate 340 of FIG. 3D, the substrate 460 of FIG. 4C, the substrate 480 of FIG. 4C, or a combination or variant thereof). For example, a mobile phone device 602, a laptop computer device 604, a fixed location terminal device 606, a wearable device 608, or a vehicle 610 (e.g., an automobile or an aerial device) may include a device 600. The device 600 can include, for example, the device 100 or the device 300, and/or any other device that includes a substrate with one or more embedded components described herein. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-6 may be rearranged and/or combined into a single component, process, feature, or function or embodied in several components, processes, or functions. Additional elements, components, processes, and/or functions may also be added without departing from the disclosure. It should also be noted FIGS. 1A-6 and its corresponding description in the present disclosure is not limited to dies and/or ICs. In some implementations, FIG. 1A-6 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device, and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate that includes a multilayer dielectric-metal structure, a first photoimageable dielectric (PID) layer, a second PID layer, and a first metal structure. The multilayer dielectric-metal structure includes one or more sidewalls that define an embedding region within the multilayer dielectric-metal structure. The multilayer dielectric-metal structure includes first dielectric layers and first metal layers patterned to define first metal lines. A first component is disposed within the embedding region. The first PID layer is coupled to a first surface of the multilayer dielectric-metal structure and to a first surface of the first component, where the first surface of the multilayer dielectric-metal structure is adjacent to the one or more sidewalls of the multilayer dielectric-metal structure. The second PID layer is coupled to a second surface of the multilayer dielectric-metal structure and to a second surface of the first component, where the second surface of the multilayer dielectric-metal structure is adjacent to the one or more sidewalls of the multilayer dielectric-metal structure and is opposite the first surface of the multilayer dielectric-metal structure. The first metal structure includes a portion in contact with at least one of the one or more sidewalls of the multilayer dielectric-metal structure and at least one sidewall of the first component, where the portion of the first metal structure is electrically coupled to the first component and the first metal lines.

Example 2 includes the device of Example 1, where the first component comprises an inductor device including one or more coils.

Example 3 includes the device of Example 2, where the one or more coils define a coil axis oriented along a first direction that is substantially parallel with respect to a normal of at least one of the one or more sidewalls of the multilayer dielectric-metal structure.

Example 4 includes the device of Example 1, where the first component comprises a heat sink, and where the substrate further includes one or more second metal structures that define thermal conduction paths between the heat sink and one or more surfaces of the substrate.

Example 5 includes the device of any of Examples 1 to 4, where the substrate further comprises a third PID layer disposed within the embedding region in contact with at least one sidewall of the first component and in contact with at least one of the one or more sidewalls of the multilayer dielectric-metal structure.

Example 6 includes the device of any of Examples 1 to 5, where the substrate further includes one or more additional components disposed within the embedding region. The one or more additional components include a second component. The substrate also includes a second metal structure including a portion in contact with at least one of the one or more sidewalls of the multilayer dielectric-metal structure and at least one sidewall of the second component, where the portion of the second metal structure electrically couples the second component and the first metal lines.

Example 7 includes the device of Example 6, where the substrate further includes a third metal structure including a portion in contact with at least one sidewall of the first component and at least one sidewall of the second component. The portion of the third metal structure is electrically coupled to the first component and the second component.

Example 8 includes the device of Example 6 or Example 7, where the first component includes a first inductor device with a first coil axis, and the second component includes a second inductor device with a second coil axis that is oriented substantially parallel to the first coil axis.

Example 9 includes the device of any of Examples 1 to 8, where the substrate further comprises one or more second metal layers on the first PID layer and electrically coupled, by one or more conductive vias through the first PID layer, to the first metal layers.

Example 10 includes the device of Example 9, where the substrate further comprises one or more third metal layers on the second PID layer and electrically coupled, by one or more conductive vias through the second PID layer, to the first metal layers.

Example 11 includes the device of any of Examples 1 to 10 and further includes one or more traces that are directly above or directly below the first component in a closest metal layer to the first component.

According to Example 12, a device includes an integrated device and a substrate electrically coupled to the integrated device. The substrate includes a multilayer dielectric-metal structure including one or more sidewalls that define an embedding region within the multilayer dielectric-metal structure. The multilayer dielectric-metal structure includes first dielectric layers and first metal layers patterned to define first metal lines. A first component is disposed within the embedding region. A first PID layer is coupled to a first surface of the multilayer dielectric-metal structure and to a first surface of the first component, where the first surface of the multilayer dielectric-metal structure is adjacent to the one or more sidewalls of the multilayer dielectric-metal structure. A second PID layer is coupled to a second surface of the multilayer dielectric-metal structure and to a second surface of the first component, where the second surface of the multilayer dielectric-metal structure is adjacent to the one or more sidewalls of the multilayer dielectric-metal structure and is opposite the first surface of the multilayer dielectric-metal structure. The substrate includes a first metal structure including a portion in contact with at least one of the one or more sidewalls of the multilayer dielectric-metal structure and at least one sidewall of the first component, where the portion of the first metal structure is electrically coupled to the first component and the first metal lines.

Example 13 includes the device of Example 12, where the first component is electrically coupled to the integrated device by way of the first metal structure.

Example 14 includes the device of Example 12 or Example 13, where the first component comprises an inductor device including one or more coils.

Example 15 includes the device of Example 14, where the one or more coils define a coil axis oriented along a first direction that is substantially parallel with respect to a normal of at least one of the one or more sidewalls of the multilayer dielectric-metal structure.

Example 16 includes the device of Example 12, where the first component comprises a heat sink, and where the substrate further comprises one or more second metal structures that define thermal conduction paths between the heat sink and the integrated device.

Example 17 includes the device of any of Examples 12 to 16, where the substrate further includes a third PID layer disposed within the embedding region in contact with at least one sidewall of the first component and in contact with at least one of the one or more sidewalls of the multilayer dielectric-metal structure.

Example 18 includes the device of any of Examples 12 to 17, where the substrate further includes one or more additional components disposed within the embedding region. The one or more additional components including a second component. The substrate also includes a second metal structure including a portion in contact with at least one of the one or more sidewalls of the multilayer dielectric-metal structure and at least one sidewall of the second component, where the portion of the second metal structure electrically couples the second component and the first metal lines.

Example 19 includes the device of Example 18, where the substrate further includes a third metal structure including a portion in contact with at least one sidewall of the first component and at least one sidewall of the second component, the portion of the third metal structure is electrically coupled to the first component and the second component.

Example 20 includes the device of Example 18 or Example 19, where the first component includes a first inductor device with a first coil axis, and the second component includes a second inductor device with a second coil axis that is oriented substantially parallel to the first coil axis.

Example 21 includes the device of any of Examples 12 to 20, where the substrate further includes one or more second metal layers on the first PID layer and electrically coupled, by one or more conductive vias through the first PID layer, to the first metal layers.

Example 22 includes the device of Example 21, where the substrate further includes one or more third metal layers on the second PID layer and electrically coupled, by one or more conductive vias through the second PID layer, to the first metal layers.

Example 23 includes the device of any of Examples 12 to 22 and further includes one or more traces that are directly above or directly below the first component in a closest metal layer to the first component.

According to Example 24, a method of fabrication includes positioning a first component within an opening of an embedding region defined by one or more sidewalls of a multilayer dielectric-metal structure, where the multilayer dielectric-metal structure includes first dielectric layers and first metal layers patterned to define first metal lines. The method includes forming a PID layer on the one or more sidewalls of the multilayer dielectric-metal structure and on one or more sidewalls of the first component. The method includes forming a first metal structure including a portion in contact with at least one of the one or more sidewalls of the multilayer dielectric-metal structure and at least one of the one or more sidewalls of the first component, where the portion of the first metal structure is electrically coupled to the first component and the first metal lines. The method includes forming one or more additional PID layers on one or more surfaces of the multilayer dielectric-metal structure that are adjacent to the one or more sidewalls of the multilayer dielectric-metal structure.

Example 25 includes the method of Example 24 and further includes electrically coupling an integrated device to the first component by way of the first metal structure.

Example 26 includes the method of Example 24 or Example 25, where the first component includes an inductor device including one or more coils.

Example 27 includes the method of Example 26, where the one or more coils define a coil axis, and where said positioning the first component within the opening includes orienting the coil axis along a first direction that is substantially parallel with respect to a normal of at least one of the one or more sidewalls of the multilayer dielectric-metal structure.

Example 28 includes the method of Example 24 or Example 25, where the first component includes a heat sink. The method further includes forming one or more second metal structures coupled to the first component and coupling an integrated device to the one or more second metal structures to define thermal conduction paths between the heat sink and the integrated device.

Example 29 includes the method of any of Examples 24 to 28 and further includes positioning one or more additional components within the opening of the embedding region, where the one or more additional components include a second component. The method further includes forming a second metal structure including a portion in contact with at least one of the one or more sidewalls of the multilayer dielectric-metal structure and at least one sidewall of the second component, where the portion of the second metal structure electrically couples the second component and the first metal lines.

Example 30 includes the method of Example 29 and further includes forming a third metal structure including a portion in contact with at least one sidewall of the first component and at least one sidewall of the second component, the portion of the third metal structure is electrically coupled to the first component and the second component.

Example 31 includes the method of Example 30, where the first metal structure, the second metal structure, and the third metal structure are formed simultaneously.

Example 32 includes the method of any of Examples 24 to 31 and further includes forming one or more additional metal layers on the one or more additional PID layers and electrically coupled, by way of one or more conductive vias, to the first metal layers.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate comprising:
a multilayer dielectric-metal structure including one or more sidewalls that define an embedding region within the multilayer dielectric-metal structure, the multilayer dielectric-metal structure including:
first metal layers patterned to define first metal lines; and
first dielectric layers;
a first component disposed within the embedding region;
a first photoimageable dielectric (PID) layer coupled to a first surface of the multilayer dielectric-metal structure and to a first surface of the first component, wherein the first surface of the multilayer dielectric-metal structure is adjacent to the one or more sidewalls of the multilayer dielectric-metal structure;
a second PID layer coupled to a second surface of the multilayer dielectric-metal structure and to a second surface of the first component, wherein the second surface of the multilayer dielectric-metal structure is adjacent to the one or more sidewalls of the multilayer dielectric-metal structure and is opposite the first surface of the multilayer dielectric-metal structure; and
a first metal structure including a portion in contact with at least one of the one or more sidewalls of the multilayer dielectric-metal structure and at least one sidewall of the first component, wherein the portion of the first metal structure is electrically coupled to the first component and the first metal lines.

2. The device of claim 1, wherein the first component comprises an inductor device including one or more coils, wherein the one or more coils define a coil axis oriented along a first direction that is substantially parallel with respect to a normal of at least one of the one or more sidewalls of the multilayer dielectric-metal structure.

3. The device of claim 1, wherein the first component comprises a heat sink, and wherein the substrate further comprises one or more second metal structures that define thermal conduction paths between the heat sink and one or more surfaces of the substrate.

4. The device of claim 1, wherein the substrate further comprises:
one or more additional components disposed within the embedding region, the one or more additional components including a second component; and
a second metal structure including a portion in contact with at least one of the one or more sidewalls of the multilayer dielectric-metal structure and at least one sidewall of the second component, wherein the portion of the second metal structure electrically couples the second component and the first metal lines.

5. The device of claim 4, wherein the substrate further comprises a third metal structure including a portion in contact with at least one sidewall of the first component and at least one sidewall of the second component, the portion of the third metal structure electrically couple the first component and the second component.

6. The device of claim 4, wherein the first component includes a first inductor device with a first coil axis, and the second component includes a second inductor device with a second coil axis that is oriented substantially parallel to the first coil axis.

7. The device of claim 1, wherein the substrate further comprises one or more second metal layers on the first PID layer and electrically coupled, by one or more conductive vias through the first PID layer, to the first metal layers.

8. The device of claim 7, wherein the substrate further comprises one or more third metal layers on the second PID layer and electrically coupled, by one or more conductive vias through the second PID layer, to the first metal layers.

9. The device of claim 8, further comprising one or more traces that are directly above or directly below the first component in a closest metal layer to the first component.

10. A device comprising:
an integrated device; and
a substrate electrically coupled to the integrated device, the substrate comprising:
a multilayer dielectric-metal structure including one or more sidewalls that define an embedding region within the multilayer dielectric-metal structure, the multilayer dielectric-metal structure including:
first metal layers patterned to define first metal lines; and
first dielectric layers;
a first component disposed within the embedding region;
a first photoimageable dielectric (PID) layer coupled to a first surface of the multilayer dielectric-metal structure and to a first surface of the first component, wherein the first surface of the multilayer dielectric-metal structure is adjacent to the one or more sidewalls of the multilayer dielectric-metal structure;
a second PID layer coupled to a second surface of the multilayer dielectric-metal structure and to a second surface of the first component, wherein the second surface of the multilayer dielectric-metal structure is adjacent to the one or more sidewalls of the multilayer dielectric-metal structure and is opposite the first surface of the multilayer dielectric-metal structure; and
a first metal structure including a portion in contact with at least one of the one or more sidewalls of the multilayer dielectric-metal structure and at least one sidewall of the first component, wherein the portion of the first metal structure is electrically coupled to the first component and the first metal lines.

11. The device of claim 10, wherein the first component is electrically coupled to the integrated device by way of the first metal structure.

12. The device of claim 10, wherein the first component comprises an inductor device including one or more coils, wherein the one or more coils define a coil axis oriented along a first direction that is substantially parallel with respect to a normal of at least one of the one or more sidewalls of the multilayer dielectric-metal structure.

13. The device of claim 10, wherein the first component comprises a heat sink, and wherein the substrate further comprises one or more second metal structures that define thermal conduction paths between the heat sink and the integrated device.

14. The device of claim 10, wherein the substrate further comprises:
one or more additional components disposed within the embedding region, the one or more additional components including a second component; and
a second metal structure including a portion in contact with at least one of the one or more sidewalls of the multilayer dielectric-metal structure and at least one sidewall of the second component, wherein the portion of the second metal structure electrically couples the second component and the first metal lines.

15. The device of claim 14, wherein the substrate further comprises a third metal structure including a portion in contact with at least one sidewall of the first component and at least one sidewall of the second component, the portion of the third metal structure is electrically coupled to the first component and the second component.

16. The device of claim 14, wherein the first component includes a first inductor device with a first coil axis, and the second component includes a second inductor device with a second coil axis that is oriented substantially parallel to the first coil axis.

17. A method of fabrication comprising:
positioning a first component within an opening of an embedding region defined by one or more sidewalls of a multilayer dielectric-metal structure, wherein the multilayer dielectric-metal structure includes first metal layers patterned to define first metal lines and first dielectric layers;
forming a photoimageable dielectric (PID) layer on the one or more sidewalls of the multilayer dielectric-metal structure and on one or more sidewalls of the first component;
forming a first metal structure including a portion in contact with at least one of the one or more sidewalls of the multilayer dielectric-metal structure and at least one of the one or more sidewalls of the first component, wherein the portion of the first metal structure is electrically coupled to the first component and the first metal lines; and
forming one or more additional PID layer on one or more surfaces of the multilayer dielectric-metal structure that are adjacent to the one or more sidewalls of the multilayer dielectric-metal structure.

18. The method of claim 17, further comprising electrically connecting an integrated device to the first component by way of the first metal structure.

19. The method of claim 17, wherein the first component comprises an inductor device including one or more coils, wherein the one or more coils define a coil axis, and wherein said positioning the first component within the opening includes orienting the coil axis along a first direction that is substantially parallel with respect to a normal of at least one of the one or more sidewalls of the multilayer dielectric-metal structure.

20. The method of claim 17, wherein the first component comprises a heat sink, and further comprising:
forming one or more second metal structures coupled to the first component; and
coupling an integrated device to the one or more second metal structures to define thermal conduction paths between the heat sink and the integrated device.
